(19) United States
(12) Patent Application Publication
(10) Pub. No.: US 2013/0314884 A1
(43) Pub. Date: Nov. 28, 2013

(54) ASSEMBLING METHOD OF DISPLAY DEVICE AND DISPLAY DEVICE

(71) Applicants: Yen-Yu Chen, Taipei City (TW); Cheng-Yao Huang, Taipei City (TW); San-Feng Lin, Taipei City (TW); Yung-Ho Kuo, Taipei City (TW); Yi-Chang Chen, Taipei City (TW); Ke-Ming Chen, Taipei City (TW)

(72) Inventors: Yen-Yu Chen, Taipei City (TW); Cheng-Yao Huang, Taipei City (TW); San-Feng Lin, Taipei City (TW); Yung-Ho Kuo, Taipei City (TW); Yi-Chang Chen, Taipei City (TW); Ke-Ming Chen, Taipei City (TW)

(73) Assignee: ASUSTeK COMPUTER INC., Taipei City (TW)

(21) Appl. No.: 13/899,589

(22) Filed: May 22, 2013

Related U.S. Application Data
(60) Provisional application No. 61/651,559, filed on May 25, 2012.

(30) Foreign Application Priority Data
Mar. 5, 2013 (TW) 102107733

(51) Int. Cl. H05K 13/00; H05K 7/14

(52) U.S. Cl. CPC H05K 13/00; H05K 7/14; H05K 7/1417
USPC 361/752; 361/679.01; 29/592.1; 29/825

(57) ABSTRACT

An assembling method of a display device and a display device are provided. The assembling method of the display device includes following steps: providing a first frame, wherein a first display module is disposed at the first frame; providing a bracket, wherein the bracket includes a positioning structure and a second display module is disposed at the bracket; and assembling the bracket and the first frame together via the positioning structure, so that the first display module and the second display module are partly overlapped.

### CROSS-REFERENCE TO RELATED APPLICATION

This application claims the priority benefits of U.S.A. provisional application Ser. No. 61/651,559, filed on May 25, 2012 and Taiwan application serial no. 102107733, filed on Mar. 5, 2013. The entirety of each of the above-mentioned patent applications is hereby incorporated by reference herein and made a part of this specification.

### BACKGROUND OF THE INVENTION

1. Field of the Invention

The invention relates to a display device and, more particularly, to a display device with double screens and an assembling method thereof.

2. Description of the Related Art

Nowadays, as displaying technologies develop, various display screens, such as a liquid crystal display (LCD), a plasma display panel (PDP) or an organic light-emitting diode (OLED) display, are applied to a display device in different sizes.

Moreover, an input device of electronic devices is changed from a conventional keyboard or a mouse to a touch control screen. Thus, a user can read data or input information by touching a screen of the electronic device.

Taking a notebook computer as an example, a display module is located between a back cover and a front frame of a display device. Recently, a notebook computer with double screens is produced. One of the screens is used as a display screen of the notebook computer, and the other one is used as a touch control screen. Conventionally, two display modules are assembled to corresponding frames first, and then they are combined together, which is complicated and increases configuring space of the display device.

### BRIEF SUMMARY OF THE INVENTION

An assembling method of a display device is provided. In the assembling method, two display modules are assembled to one bracket, and they are staggered via the bracket to save configuring space of the display device.

A display device which has better configuring space is also provided.

The assembling method of the display device includes following steps: providing a first frame, wherein a first display module is disposed at the first frame; providing a bracket, wherein the bracket includes a positioning structure and a second display module is disposed at the bracket; and assembling the bracket and the first frame together via the positioning structure to make the first display module and the second display module partly overlapped with each other.

The display device includes a bracket, a first display module, a second display module and a first frame. The bracket includes a first side and a second side opposite to each other and a positioning structure. The first display module is disposed at the first side of the bracket. The second display module is disposed at the second side of the bracket. The first frame is assembled to the bracket via the positioning structure. The second display module and the first display module are partly overlapped.

These and other features, aspects and advantages of the present invention will become better understood with regard to the following description, appended claims, and accompanying drawings.

### BRIEF DESCRIPTION OF THE DRAWINGS

FIG. 1 is a schematic diagram showing a display device in an embodiment.

FIG. 2 is a partial diagram showing a bracket and a first frame in FIG. 1.

FIG. 3 is a flow chart showing an assembling method of the display device in FIG. 1.

FIG. 4A to FIG. 4F are schematic diagrams showing assembling steps of the assembling method of the display device in FIG. 1.

### DETAILED DESCRIPTION OF THE EMBODIMENTS

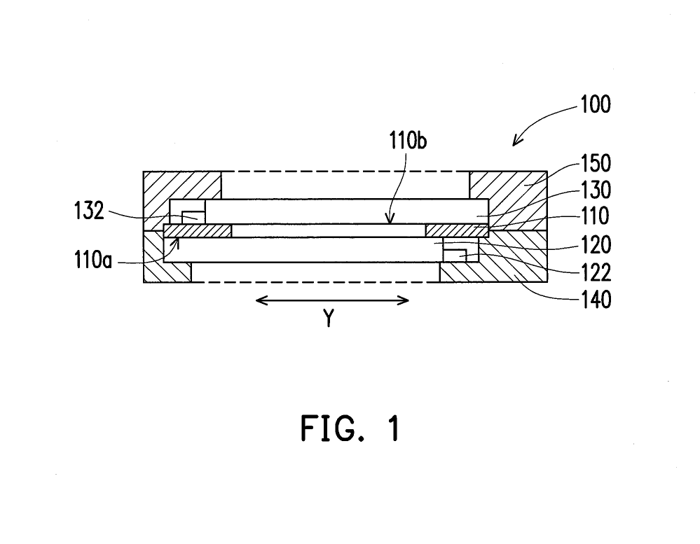

FIG. 1 is a schematic diagram showing a display device in an embodiment.

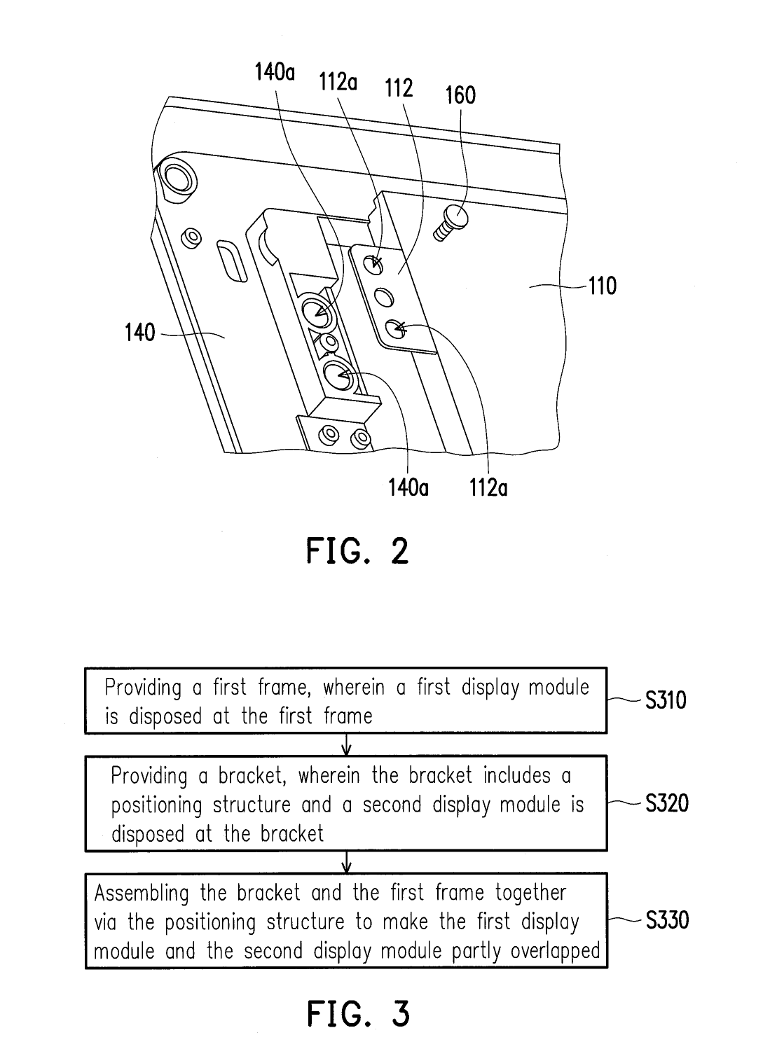

FIG. 2 is a partial diagram showing a bracket and a first frame in FIG. 1. Only one corner of the first frame is shown in FIG. 2, and the relating components and structures in FIG. 1 corresponding to FIG. 2 are partly shown.

The display device 100 may be a display with double screens and it is installed at a host of an electronic device. When the display device 100 is opened relatively to the host of the electronic device, the electronic device can be used as a notebook computer. When the display device 100 is closed relatively to the host of the electronic device, the electronic device can be used as a tablet computer.

In the embodiment, the display device 100 includes a bracket 110, a first display module 120, a second display module 130 and a first frame 140. The first frame 140 is attached to the first display module 120, and the first display module 120 is used as a display screen of a tablet computer. The second display module 130 is attached to the bracket 110, and the second display module 130 is used as a display screen of a notebook computer. The first display module may also be used as a display screen of a notebook computer, and the second display module also may be used as a display screen of a tablet computer. Moreover, the first display module 120 and the second display module 130 include a touch control panel used as a touch control screen, respectively, and the sizes of the touch control panels of the first display module 120 and the second display module 130 are the same. The user can see the first display module 120 through a part of the first frame 140 shown in a dotted line in FIG. 1.

The bracket 110 includes a first side 110a and a second side 110b opposite to each other, and a positioning structure 112. The first display module 120 is disposed at the first side 110a of the bracket 110, and the second display module 130 is disposed at the second side 110b of the bracket 110. The first frame 140 is assembled to the bracket 110 via the positioning structure 112, and the second display module 130 and the first display module 120 are partly overlapped.

In the display device 100, the first display module 120 and the second display module 130 are assembled at the same bracket 110. Thus, the configuring space of the display device 100 is saved, and the first display module 120 and the second display module 130 are partly overlapped (that is, staggered) via the bracket 110 to reduce the length of the display device 100 along the direction Y in FIG. 1.

The display device further includes a second frame 150. The second frame 150 is assembled to the bracket 110. According to this configuration, the second display module 130 is located between the second frame 150 and the bracket 110, and the first display module 120 is located between the first frame 140 and the bracket 110. The second frame 150 may be locked to the bracket 110, which is not limited herein. The user can see the second display module 130 through a part of the second frame 150 shown in a dotted line in FIG. 1.

The first display module 120 includes a first circuit board 122. The second display module 130 includes a second circuit board 132. The first circuit board 122 is electrically connected to the first display module 120. The second circuit board 132 is electrically connected to the second display module 130. The first display module 120 and the second display module 130 both include relating components of a display module, such as a light source, a reflecting sheet, a light guide plate and a diffuser.

Since the first display module 120 and the second display module 130 are partly overlapped, their un-overlapped space can be used as a spare configuring space. When the first circuit board 122 and the second circuit board 132 are disposed at the first display module 120 and the second display module 130, respectively, the first circuit board 122 is partly overlapped with the second display module 130, and the second circuit board 132 is partly overlapped with the first display module 120. That is, a part of the first circuit board 122 and the second circuit board 132 are covered by the second display module 130 and the first display module 120 correspondingly, which saves the configuring space for the first display module 120 and the second display module 130.

In the embodiment, the display device 100 further includes a plurality of locking elements 160 (only one locking element 160 is shown in FIG. 2). The positioning structure 112 may be a protruding structure disposed at an edge of the bracket 110, and it includes a plurality of first locking holes 112a. The first frame 140 includes a plurality of second locking holes 140a corresponding to the first locking holes 112a. The locking elements 160 are locked to the first locking holes 112a and the second locking holes 140a to assemble the bracket 110 and the first frame 140 together. The number and positions of the positioning structure 112, the first locking holes 112a and the second locking holes 140a are not limited, as long as they can assemble the bracket 110 and the first frame 140 together and the first display module 120 and the second display module 130 are partly overlapped.

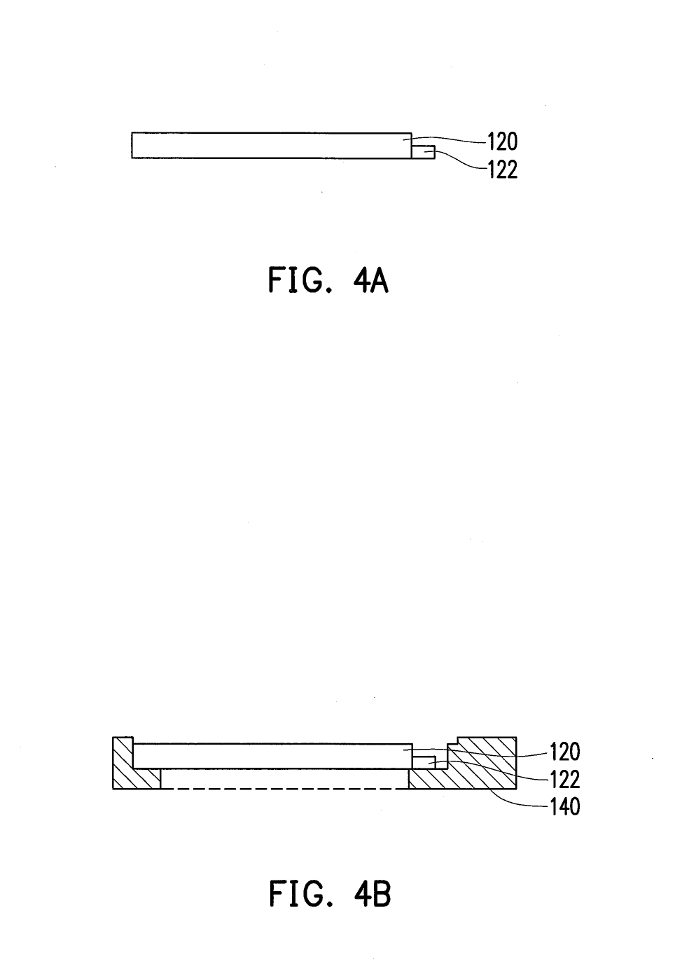

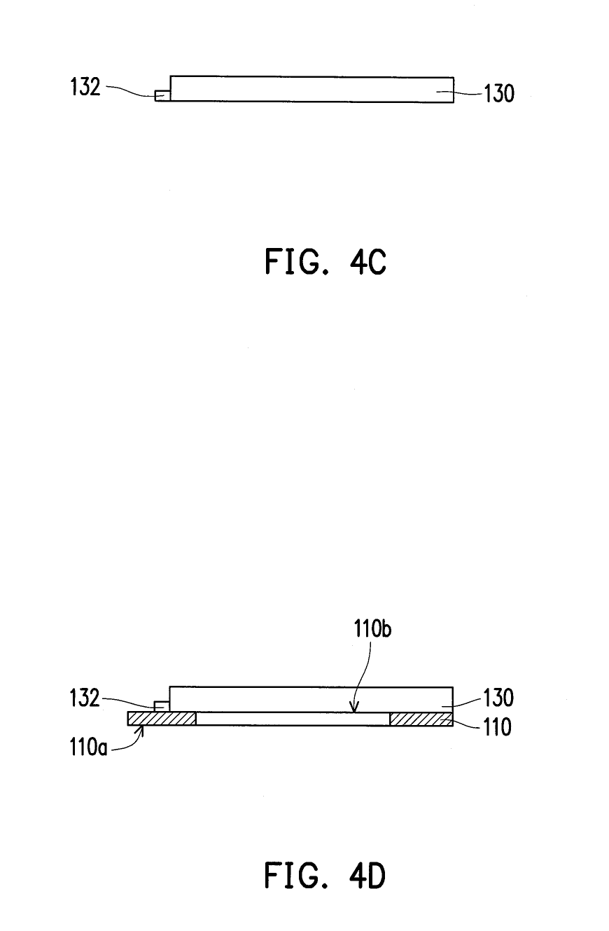

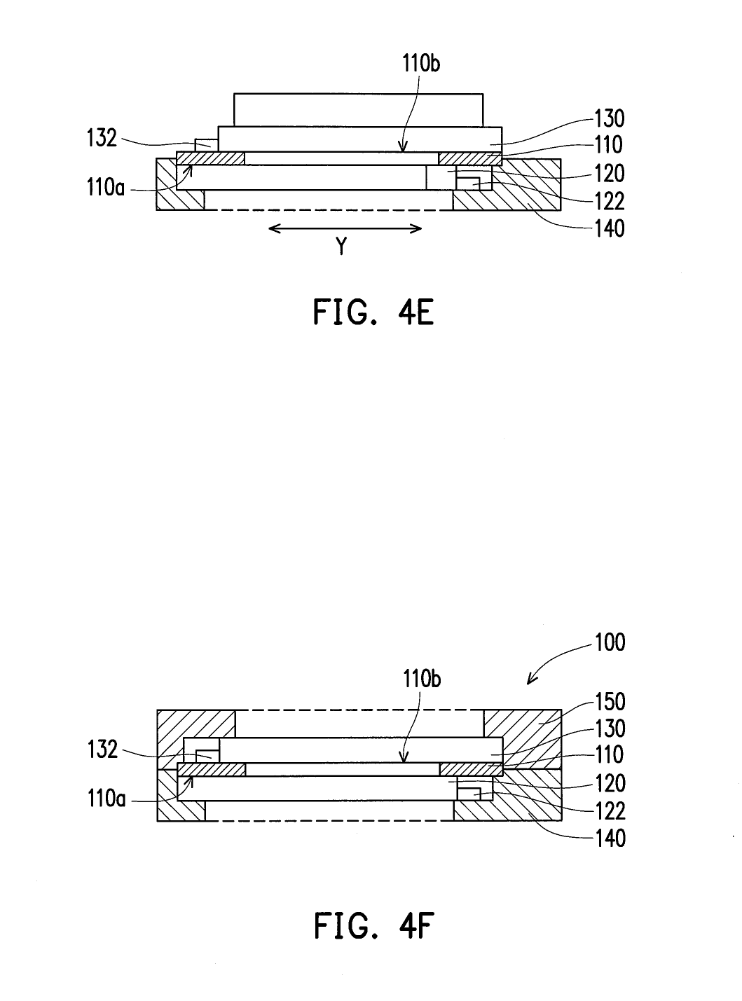

FIG. 3 is a flow chart showing an assembling method of the display device in FIG. 1. FIG. 4A to FIG. 4F are schematic diagrams showing assembling steps of the assembling method of the display device in FIG. 1. The relating components and structures in FIG. 4A to FIG. 4F corresponding to those in FIG. 2 are partly shown. As shown in FIG. 4A, the first display module 120 is first provided. The first display module 120 includes the first circuit board 122 and relating components of a display module, such as a light source, a reflecting sheet, a light guide plate and a diffuser. In FIG. 4B, the first frame 140 is provided. The first display module 120 is disposed at the first frame 140 (step S310), which means, the first display module 120 is attached to the first frame 140.

In FIG. 4D, the bracket 110 is provided. The bracket 110 includes the positioning structure 112 (as shown in FIG. 2) and the second display module 130 is disposed therein (step S320).

In step S320, the second display module 130 is first provided, as shown in FIG. 4C. The second display module 130 includes the second circuit board 132 and relating components of a display module, such as a light source, a reflecting sheet, a light guide plate and a diffuser. Then, the second display module 130 is attached to the bracket 110.

The sequence of providing the first frame 140 and the bracket 110 is not limited to that in the embodiment.

In FIG. 4E, the bracket 110 and the first frame 140 are assembled together via the positioning structure 112, and the second display module 130 and the first display module 120 are partly overlapped (step S330). In the embodiment, the first display module 120 is disposed at the first side 110a of the bracket 110, and the second display module 130 is assembled at the second side 110b of the bracket 110, which means, the first display module 120 and the second display module 130 are disposed at opposite sides of the bracket 110.

In the display device 100, the first display module 120 and the second display module 130 are disposed at the same the bracket 110. Thus, the assembling process of the display device 100 can be simplified. Moreover, the first display module 120 and the second display module 130 are partly overlapped (that is, staggered) via the bracket 110 to reduce the length of the display device 100 along the direction Y in FIG. 4E.

In step S330, since the first display module 120 and the second display module 130 are partly overlapped, their un-overlapped space can be used as a spare configuring space. After the bracket 110 is assembled to the first frame 140, the first circuit board 122 is partly overlapped with the second display module 130, and the second circuit board 132 is partly overlapped with the first display module 120, which saves the configuring space of the first display module 120 and the second display module 130.

Please refer to FIG. 4F, in step S330, the bracket 110 is assembled to the first frame 140. The assembling method of the display device 100 further includes a step of assembling the second frame 150 and the bracket 110. The second display module 130 is located between the second frame 150 and the bracket 110, and the first display module 120 is located between the first frame 140 and the bracket 110. Moreover, the second frame 150 may be locked to the bracket 110, which is not limited herein.

In sum, in the display device and the assembling method of the display device, the first display module and the second display module are disposed at the same bracket. Thus, the configuring space of the display device is saved and the assembling process of the display device is simplified. Moreover, the first display module and the second display module are partly overlapped (that is, staggered) via the bracket to reduce the longitudinal length of the display device.

Moreover, since the first display module and the second display module are partly overlapped and their un-overlapped space can be used as a spare configuring space. As a result, the first circuit board can be partly overlapped with the second display module, and the second circuit board can be partly overlapped with the first display module to saves the configuring space for the first circuit board and the second circuit board.

Although the present invention has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. An assembling method of a display device comprises following steps:
providing a first frame, wherein a first display module is disposed at the first frame;
providing a bracket, wherein the bracket includes a positioning structure and a second display module is disposed at the bracket; and
assembling the bracket and the first frame together via the positioning structure to make the first display module and the second display module partly overlapped with each other.

2. The assembling method of the display device according to claim 1, wherein the first display module includes a first circuit board, the second display module includes a second circuit board, and after the bracket is assembled to the first frame, the first circuit board is partly overlapped with the second display module, and the second circuit board is partly overlapped with the first display module.

3. The assembling method of the display device according to claim 1, wherein the display device further includes a second frame, after the bracket is assembled to the first frame, the second frame is assembled to the bracket, the second display module is located between the second frame and the bracket, and the first display module is located between the first frame and the bracket.

4. The assembling method of the display device according to claim 1, wherein the first frame is attached to the first display module, and the second display module is attached to the bracket.

5. A display device, comprising:
a bracket including a first side and a second side opposite to each other and a positioning structure;
a first display module disposed at the first side of the bracket;
a second display module disposed at the second side of the bracket; and
a first frame assembled to the bracket via the positioning structure, wherein the second display module and the first display module are partly overlapped.

6. The display device according to claim 5, wherein the first display module includes a first circuit board, the second display module includes a second circuit board, the first circuit board is electrically connected to the first display module, the second circuit board is electrically connected to the second display module, the first circuit board is partly overlapped with the second display module, and the second circuit board is partly overlapped with the first display module.

7. The display device according to claim 5, wherein the display device further includes:
a plurality of locking elements, wherein the positioning structure includes a plurality of first locking holes, the first frame includes a plurality of second locking holes corresponding to the first locking hole, and the locking elements are locked to the first locking holes and the second locking holes.

8. The display device according to claim 5, wherein the display device further includes:
a second frame assembled to the bracket, wherein the second display module is located between the second frame and the bracket, and the first display module is located between the first frame and the bracket.
